(19) United States
(12) Patent Application Publication
(10) Pub. No.: US 2026/0246447 A1
(43) Pub. Date: Aug. 20, 2026

(54) INDUCTOR FREE CONFIGURATION FOR WIDE BAND FILTER

(71) Applicant: Murata Manufacturing Co., Ltd., Nagaokakyo-shi (JP)

(72) Inventors: Sean McHUGH, Santa Barbara, CA (US); Kurt Raihn, Grass Valley, CA (US); Patrick Turner, Portola Valley, CA (US)

(21) Appl. No.: 19/536,626

(22) Filed: Feb. 11, 2026

Related U.S. Application Data
(60) Provisional application No. 63/758,428, filed on Feb. 14, 2025.
(60) Provisional application No. 63/821,759, filed on Jun. 11, 2025.

(51) Int. Cl. H03H 9/17; H03H 3/02; H03H 9/56

(52) U.S. Cl. CPC H03H 9/173; H03H 3/02; H03H 9/568

(57) ABSTRACT

A filter device is provided that includes series resonators connected between a pair of ports, and shunt resonators that are each connected between a ground connection and a node between a pair of the series resonators or between the ground connection and a node between one port and one series resonator. Each of the resonators are vertically excited acoustic resonators that comprise a piezoelectric layer having first and second surfaces, a first conductive layer on the first surface of the piezoelectric layer, and a second conductive layer on the second surface of the piezoelectric layer. The shunt resonators are each connected to the ground connection without an inductor disposed therebetween.

### CROSS REFERENCE TO RELATED APPLICATIONS

The current application claims priority to U.S. Patent Provisional Application No. 63/758,428, filed Feb. 14, 2025, and to U.S. Patent Provisional Application No. 63/821,759, filed Jun. 11, 2025, the entire contents of each of which are hereby incorporated by reference.

### TECHNICAL FIELD

This disclosure relates to radio frequency filters using acoustic wave resonators, and, more specifically, to a wideband filter including acoustic wave resonators with an inductor free configuration.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

Accordingly, as described herein, a band-pass filter and a radio frequency module including the same is provided with an inductor free configuration.

In an exemplary aspect, a filter device is provided that includes at least three series resonators connected between a pair of ports; and at least two shunt resonators that are each connected between a ground connection and a node between a pair of the at least three series resonators or between the ground connection and a node between one port of the pair of ports and one series resonator of the at least three series resonators. In this aspect, each of the at least three series resonators and the at least two shunt resonators each comprise: a piezoelectric layer having a first surface and a second surface opposite the first surface, at least one first conductive layer on the first surface of the piezoelectric layer, and a second conductive layer on the second surface of the piezoelectric layer. Moreover, the at least two shunt resonators are each connected to the ground connection without an inductor disposed therebetween.

In another exemplary aspect, the filter device includes a residual inductance between each of the at least two shunt resonators and the ground connection that is equal to or less than 0.1 nanohenries (nH).

In another exemplary aspect of the filter device, the at least three series resonators and the at least two shunt resonators are structurally configured to provide a fractional bandwidth of at least 25% relative to a bandwidth of the filter device.

Moreover, in another exemplary aspect of the filter device, the at least three series resonators and the at least two shunt resonators are each vertically excited acoustic resonators that are structurally configured to provide an electromechanical coupling of at least 30% when a voltage is applied to the at least one first conductive layer and the second conductive layer.

In another exemplary aspect of the filter device, each of the at least three series resonators and the at least two shunt resonators are mounted to a single chip that comprises the pair of ports and a plurality of conductive contacts that are coupled to an external ground contact comprising the ground connection.

In another exemplary aspect, the filter device includes an additional chip that includes a pair of matching inductors that are respectively coupled to the pair of ports of the single chip and the ground connection.

In another exemplary aspect of the filter device, each of the at least three series resonators and the at least two shunt resonators further comprises a pair of busbars that includes a first busbar that is coupled to the at least one first conductive layer and a second busbar that is coupled to the second conductive layer.

In another exemplary aspect of the filter device, each of the at least three series resonators and the at least two shunt resonators further comprises a pair of busbars that includes a first busbar that is coupled to the at least one first conductive layer, and the second conductive layer of each of the at least three series resonators and the at least two shunt resonators is a floating electrode.

In another exemplary aspect of the filter device, the piezoelectric layer of each of the at least three series resonators and the at least two shunt resonators comprise lithium niobate.

In another exemplary aspect, a filter device is provided that includes at least three series resonators connected between a pair of ports; and at least two shunt resonators that are each connected between a ground connection and a node between a pair of the at least three series resonators or between the ground connection and a node between one port of the pair of ports and one of the at least three series resonators. In this aspect, the at least two shunt resonators are each connected to the ground connection without an inductor disposed therebetween, and the at least three series resonators and the at least two shunt resonators are structurally configured to provide a fractional bandwidth of at least 25% relative to a bandwidth of the filter device.

In another exemplary aspect of the filter device, each of the at least three series resonators and the at least two shunt resonators are vertically-excited acoustic resonators that each comprise: a piezoelectric layer having a first surface and a second surface opposite the first surface, at least one first conductive layer on the first surface of the piezoelectric layer, and a second conductive layer on the second surface of the piezoelectric layer.

In another exemplary aspect, a radio frequency module is provided that includes a filter device including at least three series resonators connected between a pair of ports; and at least two shunt resonators that are each connected between a ground connection and a node between a pair of the at least three series resonators or between the ground connection and a node between one port of the pair of ports and one of the at least three series resonators. In this aspect, the at least two shunt resonators are each connected to the ground connection without an inductor disposed therebetween, and the at least three series resonators and the at least two shunt resonators are structurally configured to provide a fractional bandwidth of at least 25% relative to a bandwidth of the filter device.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIGS. 1A-1C illustrate a schematic plan view and respective schematic cross-sectional views of a film bulk acoustic resonator according to an exemplary aspect.

FIGS. 2A-2C illustrate a schematic plan view and respective schematic cross-sectional views of a film bulk acoustic resonator according to another exemplary aspect.

FIGS. 2D-2F illustrate a schematic plan view and respective schematic cross-sectional views of a film bulk acoustic resonator according to another exemplary aspect.

FIG. 3A is a schematic cross-sectional view of a film bulk acoustic resonator according to an exemplary aspect.

FIG. 3B is an alternative schematic cross-sectional view of a film bulk acoustic resonator according to an exemplary aspect.

FIG. 3C illustrates a schematic plan view and respective schematic cross-sectional views of an acoustic resonator according to another exemplary aspect.

FIG. 4A illustrates a schematic plan view and a perspective view of an acoustic resonator structure that is a refinement of the exemplary aspect of the film bulk acoustic resonator shown in FIGS. 2A-2C.

FIG. 4B illustrates a cross-section view of the IDT configuration in FIG. 4A according to another exemplary aspect.

FIG. 4C illustrates a schematic plan view and a perspective view of an IDT configuration of another refinement of the exemplary aspect of the film bulk acoustic resonator shown in FIGS. 2A-2C.

FIG. 4D shows an example of an acoustic mode in a film bulk acoustic resonator according to an exemplary aspect.

FIG. 4E shows an example of an acoustic mode in a film bulk acoustic resonator according to an exemplary aspect.

FIG. 5A is a schematic block diagram of a filter using film bulk acoustic resonators according to an exemplary aspect.

FIG. 5B is a schematic diagram of a radio frequency module that includes an acoustic wave filter device according to an exemplary aspect.

FIG. 6A illustrates a filter structure implementing the acoustic resonator configurations described herein according to an exemplary aspect.

FIG. 6B illustrates a circuit diagram of a refinement of the “inductor free” ladder filter according to an exemplary aspect.

FIG. 6C illustrates a circuit diagram of a refinement of the “inductor free” ladder filter according to an exemplary aspect.

FIGS. 7A-7C illustrate simulation showing admittance for a filter device with matching inductors according to a conventional ladder filter design as described above.

FIGS. 8A-8C illustrate simulation showing admittance for a filter device with inductors according to an exemplary aspect.

FIGS. 9A and 9B compare the same general ladder configuration with a gamma value of 1.44 and with and without matching inductors as described herein.

FIG. 10 illustrates a simulation showing capacity and density according to an exemplary aspect.

FIGS. 11A and 11B illustrates exemplary layouts of the filter structure according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, and a radio frequency module are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

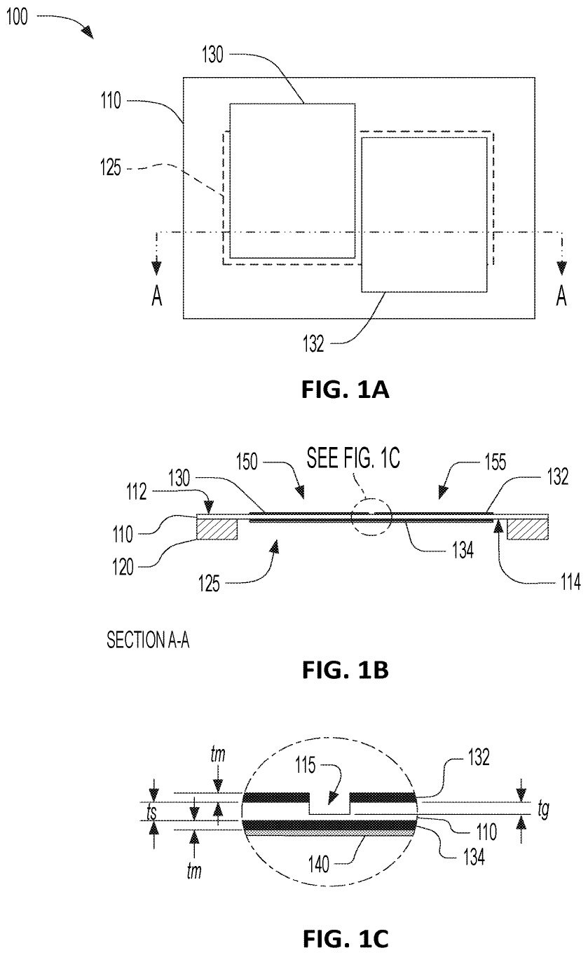

FIG. 1A illustrates a simplified top view and FIGS. 1B and 1C illustrate cross-sectional views of a film bulk acoustic resonator 100 according to an exemplary aspect. According to this aspect, the film bulk acoustic resonator 100 includes a piezoelectric layer 110 (piezoelectric plate or piezoelectric layer may be used interchangeably) having essentially parallel front and back surfaces 112, 114, respectively. In this context, “essentially parallel” means “parallel within reasonable manufacturing tolerances.” Thus, it should be appreciated that the term “parallel” generally refers to the front side 112 and back side 114 being opposing to each other and that the surfaces are not necessarily planar and parallel to each other. For example, due to the manufacturing variances result from the deposition process, the front side 112 and back side 114 may have undulations of the surface as would be appreciated to one skilled in the art. In addition, the piezoelectric layer 110 can be a thin single-crystal layer of a piezoelectric material. The term “single-crystal” does not necessarily mean entirely of a uniform crystalline structure and may include impurities due to manufacturing variances as long as the crystal structure is within acceptable tolerances.

According to the exemplary aspect, the piezoelectric layer 110 is preferably lithium niobate (LN), but may be lithium tantalate (LT), lanthanum gallium silicate, gallium nitride, or some other material. The piezoelectric layer 110 is cut such that the orientation of the X, Y, and Z crystalline axes with respect to the front and back surfaces is known and consistent. In the examples described herein, the piezoelectric layers are Z-cut, which is to say the Z axis is normal to the front and back sides 112, 114. However, film bulk acoustic resonators according to exemplary aspects may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

In an exemplary aspect, the thickness ts of the piezoelectric layer 110 may be determined from:

$$ts \approx {n}^{*} {V}_{SH} / 2 {F}_{R} ,$$

where F_{R} is a desired operation frequency, V_{SH} is the shear wave velocity of the piezoelectric layer, and n=1, 3, 5, . . . is the desired mode (overtone) number. n=1 is usually referred to as “fundamental mode” and n>1 as “overtones”.

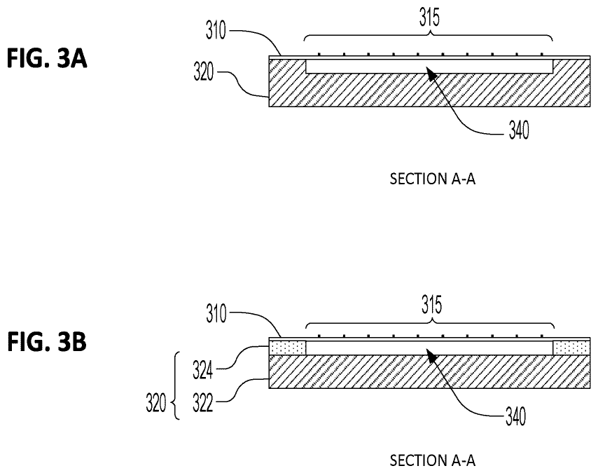

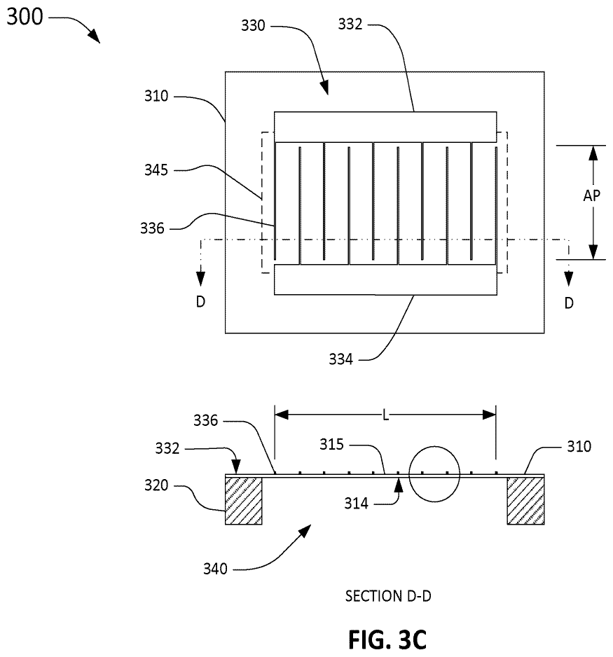

The back side 114 of the piezoelectric layer 110 is attached to a substrate 120 that provides mechanical support to the piezoelectric layer 110. The substrate 120 may be, for example, silicon, sapphire, quartz, or some other material. The piezoelectric layer 110 may be bonded to the substrate 120 using a wafer bonding process, or grown on the substrate 120, or attached to the substrate in some other manner. The piezoelectric layer may be attached directly to the substrate or may be attached to the substrate via one or more intermediate material layers as discussed below with respect to FIGS. 3A and 3B. In other words, the back side 114 of the piezoelectric layer 110 can be coupled or connected either directly or indirectly, via one or more intermediate layers (e.g., a dielectric layer, such as silicon oxide or silicon dioxide), to a surface of the substrate 120. Moreover, the phrase “supported by” or “attached” may, as used herein interchangeably, mean attached directly, attached indirectly, mechanically supported, structurally supported, or any combination thereof.

As shown in FIG. 1B, a cavity 125 is formed in the substrate 120 such that the portion of the piezoelectric layer 110 containing the front-side and back-side conductor patterns 130, 132, 134 is suspended over the cavity 125. The portion of the piezoelectric layer 110 that is over (e.g., spanning or extending over) the cavity can be referred to herein as a “diaphragm” due to its physical resemblance to the diaphragm of a microphone. The diaphragm can be contiguous with the rest of the piezoelectric layer 110 around all of a perimeter of the cavity 125. In this context, “contiguous” means “continuously connected without any intervening item”. However, the diaphragm can be configured with at least 50% of the edge surface of the diaphragm coupled to the edge of the piezoelectric layer 110 in an exemplary aspect.

According to an exemplary aspect, “cavity” has its conventional meaning of “an empty space within a solid body.” The cavity 125 may be a hole completely through the substrate 120 (as shown in Section A-A) or a recess in the substrate 120 that does not extend through the substrate 120. The cavity 125 may be formed, for example, by selective etching of the substrate 120 before or after the piezoelectric layer 110 and the substrate 120 are attached. As shown in FIG. 1B, the cavity 125 has a rectangular shape. A cavity of the film bulk acoustic resonator 100may have a different shape, such as a regular or irregular polygon. The cavity of the film bulk acoustic resonator 100 may more or fewer than four sides, which may be straight or curved.

A first front-side conductor pattern 130 (e.g., a first electrode) and a second front-side conductor pattern 132 (e.g., a second electrode) are formed on the front side 112 of the piezoelectric layer 110. A back-side conductor pattern 134 (e.g., a floating electrode) is formed on the second side 114 of the piezoelectric layer 110. The back-side conductor pattern 134 is configured to be a “floating” conductor pattern, meaning that is not electrically connected to any input signal, output signal, or ground, and has a floating electrical potential. In some cases, the back-side conductor pattern 134 is floating as it is not electrically connected to any other conductor through any direct physical wiring connection (e.g., conductive via), although there may be some capacitive coupling between the front-side conductor pattern 130 through the piezoelectric layer 110. That is, one or more capacitances may be formed between the first and second front-side conductor patterns 130 and 132 and the floating back-side conductor pattern 134, but otherwise the floating back-side conductor pattern 134 does not have any direct conductive connection to the front-side conductor pattern 130. More specifically, the back-side conductor pattern 134 can be capacitively coupled in series to the first and second front-side conductor patterns 130, 132. The conductor patterns may be molybdenum, aluminum, copper, gold, or some other conductive metal or alloy. The back-side conductor pattern and the front side conductor patterns are not necessarily the same material. In an exemplary aspect, the back-side conductor pattern 134 can be made of any appropriate electrically conductive material. For example, the back-side electrode may be gold to avoid corrosion. The portion of the piezoelectric layer 110 between the first front-side conductor pattern 130 and the back-side conductor pattern 134 forms a first capacitance 150 for a resonator. The portion of the piezoelectric layer 110 between the second front-side conductor pattern 132 and the back-side conductor pattern 134 forms a second capacitance 155 for the resonator. These capacitances are electrically in series such that an RF signal applied between the first and second front-side conductor patterns 130, 132 excites acoustic waves in the resonator 100.

According to an exemplary aspect, the diaphragm forms a seal over the cavity 125 such that the first and second front-side conductor patterns 130, 134 are not exposed to the environment adjacent to the back-side conductor pattern 134. Ideally, when an RF signal is applied between the first and second front-side conductor patterns 130, 132, the back-side conductor pattern should remain at ground potential. To this end, the first capacitance 150 should be equal to a capacitance of the second capacitance 155. Assuming the piezoelectric diaphragm has uniform thickness, the area of overlap between the first front-side conductor pattern 130 and the back-side conductor pattern 134 will be equal to the area of overlap between the second front-side conductor pattern 132 and the back-side conductor pattern 134. The back-side conductor pattern 134 will remain at ground potential when balanced signals (i.e., signals with equal amplitude and 180-degree phase difference), are applied to the first and second conductor patterns 130, 132.

According to the exemplary aspect, the piezoelectric layer 110 may be Y-cut (i.e., with the Y crystalline axis of the piezoelectric material normal to the surfaces 112, 114) or rotated Y-cut (i.e., with the Y crystalline axis of the piezoelectric material rotated by a predetermined angle with respect to normal to the surfaces 112, 114). In this case, an RF signal applied between the first and second front-side conductor patterns 130, 132 will excite shear acoustic waves in both the first and second resonators. Rotated Y-cuts can be used to achieve shear displacements exclusively in planes parallel to the surface 112, 114. Selection of the rotation angle can be used to control the electromechanical coupling of the resonators. Shear displacements parallel to the surfaces of the piezoelectric layer do not generate compressional waves in an adjacent liquid thus allowing high Q-factor operation of the resonator.

As shown in FIG. 1A, the first and second front-side conductor patterns 130 and 132 and the back-side conductor pattern 134 are rectangular in shape. However, the conductor patterns may be non-rectangular (e.g., trapezoidal, curved, or irregular) to suppress parasitic acoustic modes according to alternative aspects.

In the detailed cross-sectional view shown in FIG. 1C, the thickness of the piezoelectric layer 110 is dimension ts and the thickness of the conductor patterns 130, 132, 134 is dimension tm. The thickness ts of the piezoelectric layer 110 may be, for example, 100 nanometers (nm) to 1000 nm according to an exemplary aspect. Moreover, the thickness tm of the conductor patterns 130, 132, 134 may be, for example, 10 nm to 500 nm. The thickness of the conductor patterns may be the same or the first and second front-side conductor patterns 130 and 132 and the back-side conductor pattern 134 may have different thicknesses in an exemplary aspect. Moreover, in an exemplary aspect, one or more additional layers 140, such as a dielectric layer (e.g., silicon oxide) can be disposed on the back-side conductor pattern 134. In another aspect, the one or more additional layers 240 can be a sensor layer or the like to convert the resonator to a sensor in an exemplary aspect. For example, the one or more additional layers 240 may be, for example, a film, a monolayer, or a surface treatment that is either disposed directly on the back-side conductor pattern 234 or may be coupled to the back-side conductor pattern 234 via one or more additional an intermediate layers, such as an adhesion layer.

As further shown, the piezoelectric layer may be etched or otherwise removed, completely or only partially, in the area between the first and second front-side conductor patterns 130, 132, forming slots 115. The presence of the slots 115 may suppress lateral acoustic modes that might be excited by the electric field between the front-side conductor patterns 130, 132. A depth tg of the slot 115 can extend partially or completely through the piezoelectric layer 110.

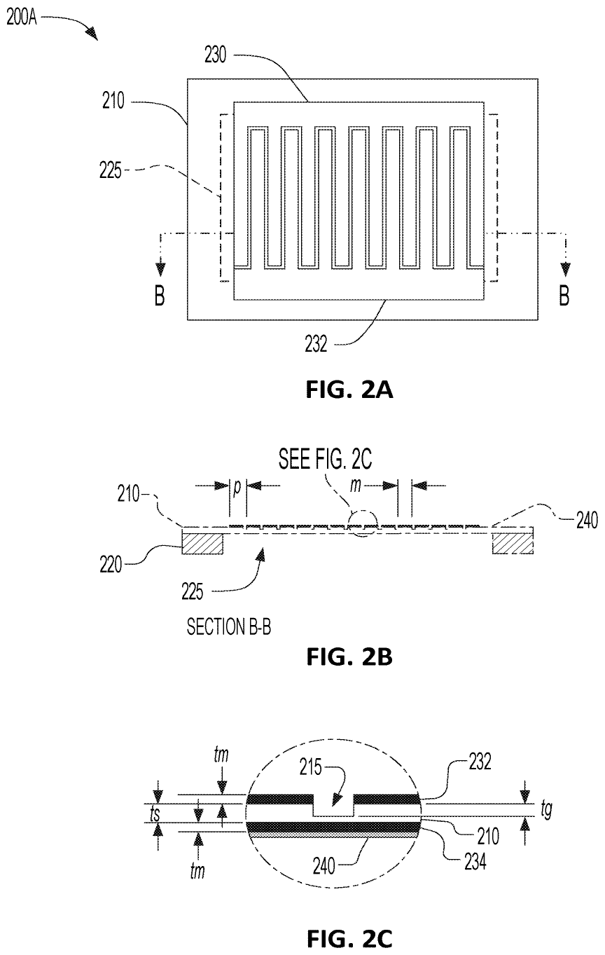

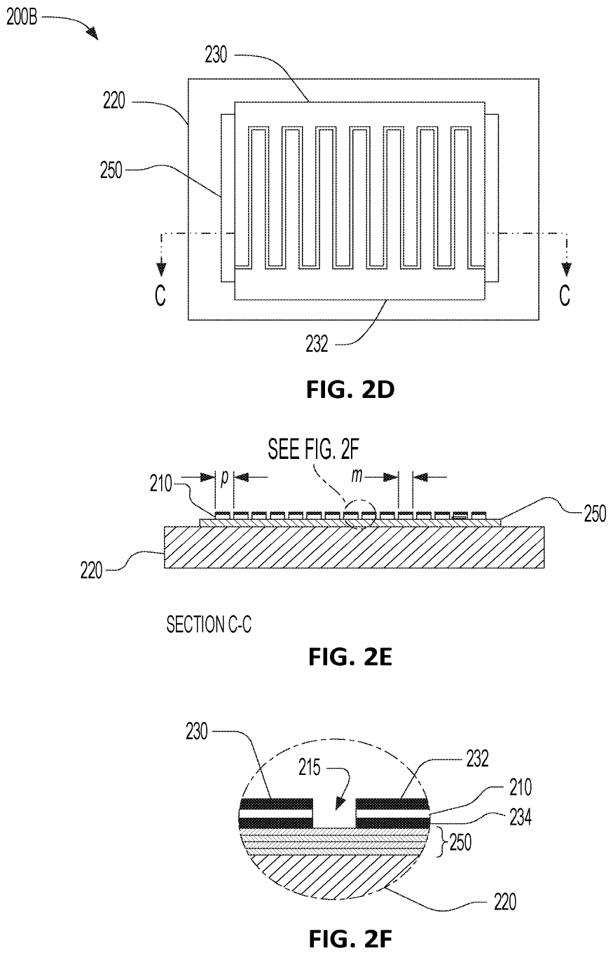

FIG. 2A illustrates a simplified top view and FIGS. 2B and 2C illustrate respective cross-sectional views of another film bulk acoustic resonator 200A. The film bulk acoustic resonator 200A is made up of a piezoelectric layer 210 attached to a substrate 220 as previously described. A cavity 225 is formed in the substrate 220 such that a portion of the piezoelectric layer 210 is suspended over the cavity 225.

First and second front-side conductor patterns 230, 232 (e.g., first and second electrodes) are formed on the front side of the piezoelectric layer (the side facing away from cavity 225). The first and second front-side conductor patterns 230, 232 form an interleaved finger pattern (IFP) similar to an interdigital transducer or IDT used in surface acoustic wave resonators. The first front-side conductor pattern 230 includes a first plurality of parallel fingers extending from a first busbar. The second front-side conductor pattern 232 includes a second plurality of parallel fingers extending from a second busbar. The first and second pluralities of parallel fingers are interleaved and most or all of the interleaved parallel fingers are disposed on the portion of the piezoelectric layer 210 suspended over the cavity 225. The width m of each finger will be a substantial portion of the pitch p, or center-to-center spacing, of the fingers. It should be appreciated that the first busbar can be considered part of the first front-side conductor pattern 230 that also includes the first plurality of parallel fingers (i.e., a single metal pattern) or it can be a separate metal pattern that is coupled to the first plurality of parallel fingers. Similarly, the second busbar can be considered part of the second front-side conductor pattern 232 that also includes the second plurality of parallel fingers (i.e., a single metal pattern) or it can be a separate metal pattern that is coupled to the second plurality of parallel fingers.

In either case, as further shown in the detailed view in FIG. 2C, slots 215 may be formed in the piezoelectric layer 210 between the interleaved fingers of the first and second front-side conductor patterns 230, 232 in an exemplary aspect. The presence of the slots 215 may suppress lateral acoustic modes that might be excited by the electric field between the front-side conductor patterns 230, 232. A depth tg of the slots 215 can extend partially or completely through the piezoelectric layer 210. The grooves also prevent spreading of vibration energy along the structure thus improving Q-factor of resonators.

A back-side conductor pattern 234 is formed on the back side of the piezoelectric layer 210 opposed to the first and second front-side conductor patterns 230, 232. A first resonator is formed between the first front-side conductor pattern 230 and the back-side conductor pattern 234. A second resonator is formed between the second front-side conductor pattern 232 and the back-side conductor pattern 234. The first and second front-side conductor patterns may have the same number of interleaved fingers. Moreover, in an exemplary aspect, one or more additional layers 240, such as a dielectric layer (e.g., silicon oxide) can be disposed on the back-side conductor pattern 234.

FIGS. 2D-2F illustrate a schematic plan view and respective schematic cross-sectional views of a film bulk acoustic resonator according to another exemplary aspect. It is noted that the plan view of film bulk acoustic resonator 200B generally comprises the same elements of film bulk acoustic resonator 200A, which includes a piezoelectric layer 210 attached to a substrate 220, and first and second front-side conductor patterns 230, 232, as previously described.

However, instead of having a cavity, film bulk acoustic resonator 200B includes an acoustic Bragg reflector 250 that is between (e.g., “sandwiched”) the substrate 220 and the back surface of the piezoelectric layer 210. The term “sandwiched” means the acoustic Bragg reflector 250 is both disposed between and physically connected to a surface of the substrate 220 and the back surface of the piezoelectric layer 210. In some circumstances, thin layers of additional materials (e.g., silicon oxide) may be disposed between the acoustic Bragg reflector 250 and the surface of the substrate 220 and/or between the acoustic Bragg reflector 250 and the back surface of the piezoelectric layer 210. Such additional material layers may be present, for example, to facilitate bonding the piezoelectric layer 210, the acoustic Bragg reflector 250, and the substrate 220.

According to the exemplary aspect, the acoustic Bragg reflector 250 includes multiple layers that alternate between materials having high acoustic impedance and materials having low acoustic impedance. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. In an exemplary aspect, each of the layers can have a thickness equal to, or about, one-fourth of the acoustic wavelength at or near a resonance frequency of the film bulk acoustic resonator 200B. Materials having comparatively low acoustic impedance include silicon dioxide, silicon oxycarbide, aluminum, titanium, and certain plastics such as cross-linked polyphenylene polymers. Materials having comparatively high acoustic impedance include silicon nitride, aluminum nitride, silicon carbide, and metals such as molybdenum, tungsten, gold, and platinum. All of the high acoustic impedance layers of the acoustic Bragg reflector 250 are not necessarily the same material, and all of the low acoustic impedance layers are not necessarily the same material.

An exemplary cross-sectional view is shown in FIG. 2F along the section plane C-C of film bulk acoustic resonator 200B. As shown, space 215 (e.g., a slot) is defined or formed in the first and second front-side conductor patterns 230, 232 and the piezoelectric layer 210 to provide acoustic isolation between adjacent fingers. The space or cavity may be formed in the respective layers by etching or otherwise removed to effectively form slots as slot 215. The presence of the slot 215 suppresses lateral acoustic modes that might be excited by the electric field between the front-side conductor patterns 230, 232.

FIG. 3A and FIG. 3B show two exemplary cross-sectional views along the section plane B-B defined in FIGS. 2A-2C of film bulk acoustic resonator 200A. It is noted that the configurations shown in FIGS. 3A and 3B may also be implemented for the film bulk acoustic resonator configuration shown in FIGS. 1A-1C. In FIG. 3A, a piezoelectric layer 310, which corresponds to piezoelectric layer 210, is attached directly to a substrate 320, which can correspond to substrate 220 of FIG. 2B. Moreover, a cavity 340, which does not fully penetrate the substrate 320, is formed in the substrate under the portion (i.e., the diaphragm 315) of the piezoelectric layer 310 containing the interleaved fingers of the IDT of a film bulk acoustic resonator. The cavity 340 can correspond to cavity 225 of FIG. 2B and/or the cavity 125 of FIG. 1B. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324, either entirely within the intermediate layer 324 or at least partially in the intermediate layer 324, under the portion (i.e., the diaphragm 315) of the piezoelectric layer 310 containing the IDT fingers of a film bulk acoustic resonator. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to the diaphragm of either FIG. 1B and/or FIG. 2B, for example, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects. It is also noted while the exemplary aspect contemplates the resonator structures utility a membrane-based resonator structure, the resonator structures can be solidly mounted on metallic Bragg stack (mirror or reflector) for improved reliability in an alternative aspect.

The acoustic resonator configurations described above with respect to FIGS. 3A and 3B include a diaphragm spanning over a cavity. However, in an alternative aspect, the acoustic resonator can be solidly mounted in which the diaphragm with IDT fingers is mounted on or above a Bragg mirror, which in turn can be mounted on a substrate.

That is, in contrast to the film bulk acoustic resonator device shown in FIG. 3B, the IDT of a solidly-mounted (“SM”) film bulk acoustic resonator can include an acoustic reflector, such as a Bragg mirror, that is sandwiched between substrate 220 and the back surface of the piezoelectric layer 310. The term “sandwiched” means the acoustic reflector is both disposed between and mechanically attached to the substrate 220 and the back surface of the piezoelectric layer 310 and there is no cavity therebetween, such as cavity 340 in FIG. 3B. In some circumstances, layers of additional materials (e.g., one or more dielectric layers) may be disposed between the acoustic reflector and the surface of the substrate 220 and/or between the acoustic reflector and the back surface of the piezoelectric layer 310. Such additional material layers may be present, for example, to facilitate bonding the piezoelectric layer, the acoustic reflector, and the substrate.

The acoustic reflector may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. Dielectric materials having comparatively low acoustic impedance include silicon dioxide, carbon-containing silicon oxide, and certain plastics such as cross-linked polyphenylene polymers. Materials that have comparatively high acoustic impedance include hafnium oxide, silicon nitride, aluminum nitride, silicon carbide. All of the high acoustic impedance layers of the acoustic reflector are not necessarily the same material, and all of the low acoustic impedance layers are not necessarily the same material.

FIG. 3C shows a simplified schematic top view and orthogonal cross-sectional view of an acoustic resonator device, namely a transversely excited film bulk acoustic resonator (XBAR) 300 according to another exemplary aspect. The cross-sectional view is taken along the Section D-D. Moreover, it is generally noted that the XBAR 300 shown in FIG. 3C can be another exemplary aspect of the resonators generally shown in FIGS. 3A and/or 3B as described above.

According to the exemplary aspect, XBAR 300 includes a conductor pattern (e.g., a thin film metal layer) formed at one or both surfaces of a piezoelectric layer 310 having parallel front side 312 and a back side 314, respectively (also referred to generally first and second surfaces, respectively). It should be appreciated that the term “parallel” generally refers to the front side 312 and back side 314 being opposing to each other and that the surfaces are not necessarily planar and exactly parallel to each other. For example, due to the manufacturing variances result from the deposition process, the front side 312 and back side 314 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage, such as +10%) in practice due to possible manufacturing variances as would be appreciated to one skilled in the art.

According to an exemplary aspect, the piezoelectric layer is a thin layer of a piezoelectric material, such as lithium niobate, lithium tantalate, lanthanum gallium silicate, gallium nitride, or aluminum nitride. The back side 314 of the piezoelectric layer 310 may be at least partially supported by a surface of the substrate 320 except for a portion of the piezoelectric layer 310 that forms a diaphragm 315 that is over (e.g., spanning or extending over) a cavity 340 in one or more layers below the piezoelectric layer 310 such as one or more intermediate layers above or in the substrate. In other words, the back side 314 of the piezoelectric layer 310 can be coupled or connected either directly to a surface of the substrate 320 (e.g., as shown in FIG. 3A) or indirectly via one or more intermediate layers (e.g., a dielectric layer, such as a silicon oxide layer) to a surface of the substrate 320 (e.g., as shown in FIG. 3B). Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 315 due to its physical resemblance to the diaphragm of a microphone. As shown in FIG. 3C, the diaphragm 315 is contiguous with the rest of the piezoelectric layer 310 around all of a perimeter 345 of the cavity 340. In this context, “contiguous” means “continuously connected without any intervening item”. However, the diaphragm 315 can be configured with at least 50% of the edge surface of the diaphragm 315 coupled to the edge of the piezoelectric layer 310 in an exemplary aspect.

According to the exemplary aspect, the substrate 320 is configured to provide mechanical support to the piezoelectric layer 310. Similar to the configurations descried above, the substrate 320 may be, for example, silicon, sapphire, quartz, or some other material or combination of materials. The back side 314 of the piezoelectric layer 310 may be bonded to the substrate 320 using a wafer bonding process.

As shown, the conductor pattern of the XBAR 300 includes an interdigital transducer (IDT) 330. The IDT 330 includes a first plurality of parallel fingers, such as finger 336, extending from a first busbar 332 and a second plurality of fingers extending from a second busbar 334. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 330 is the “length” of the IDT.

In the example of FIG. 3C, the IDT 330 is at the surface of the front side 312 (e.g., the first surface) of the piezoelectric layer 310. However, as discussed below, in other configurations, the IDT 330 may be at the surface of the back side 314 (e.g., the second surface) of the piezoelectric layer 310 or at both the surfaces of the front and back sides 312, 314 of the piezoelectric layer 310, respectively.

The first and second busbars 332, 334 are configured as the terminals of the XBAR 300 with the plurality of interleaved fingers extending therefrom. In operation, a radio frequency signal or microwave signal applied between the two busbars 332, 334 of the IDT 330 primarily excites an acoustic mode (i.e., a primarily shear acoustic mode) within the piezoelectric layer 310. As will be discussed in further detail, the primarily excited shear acoustic mode is a bulk shear mode or bulk acoustic wave where acoustic energy of a bulk shear acoustic wave is excited in the piezoelectric layer 310 by the IDT 330 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 332, 334, the RF voltage applied to the respective sets of IDT fingers generates a time-varying electric field that is laterally excited with respect to a surface of the piezoelectric layer 310. Thus, in some cases the primarily excited acoustic mode may be commonly referred to as a laterally excited bulk acoustic wave since displacement, as opposed to propagation, occurs primarily in the direction of the bulk of the piezoelectric layer.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 332, 334 of the IDT 330, heat is generated that must be dissipated from the resonator for improved performance. In general, heat can be dissipated by lateral conduction on the membrane (e.g., in the electrodes themselves), and vertical conduction through a cavity to substrate.

In any event, the IDT 330 is positioned at or on the piezoelectric layer 310 such that at least the fingers of the IDT extend at or on the portion of the piezoelectric layer 310 that is over the cavity 340, for example, the diaphragm 315 as described herein. As shown in FIG. 3C, the cavity 340 has a rectangular cross section with an extent greater than the aperture AP and length L of the IDT 330. According to other exemplary aspects, the cavity of an XBAR may have a different cross-sectional shape, such as a regular or irregular polygon. The cavity of an XBAR may have more or fewer than four sides, which may be straight or curved.

For ease of presentation in FIG. 3C, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

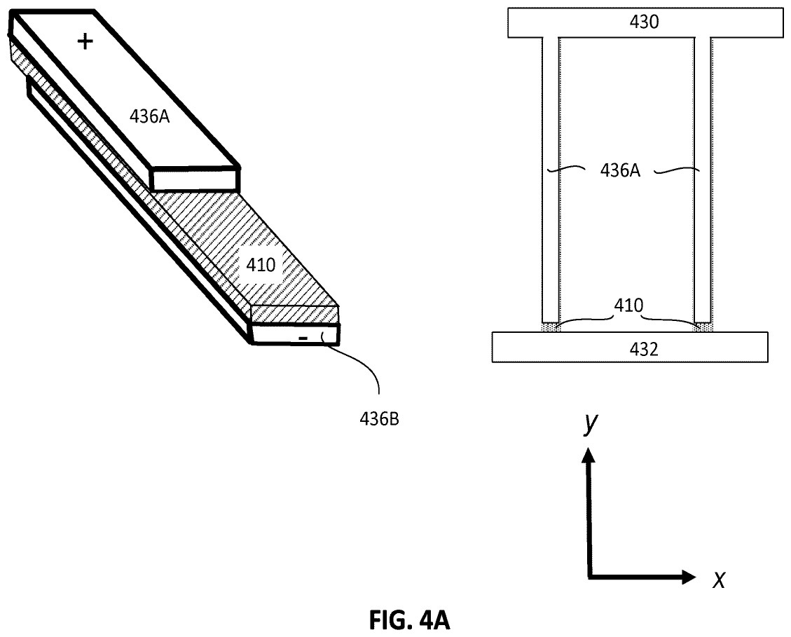

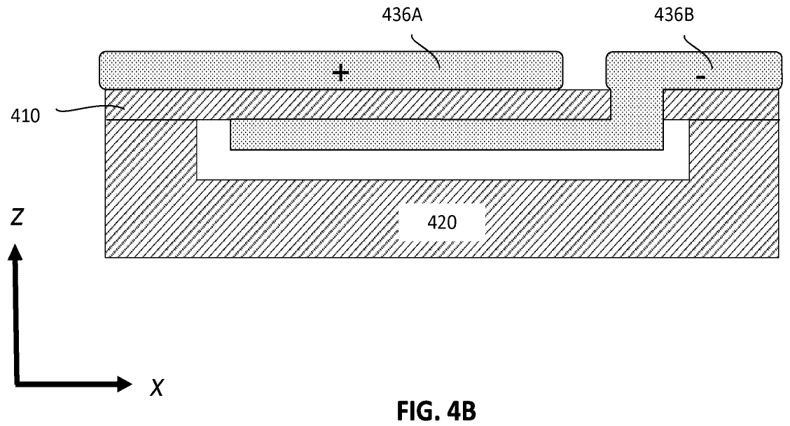

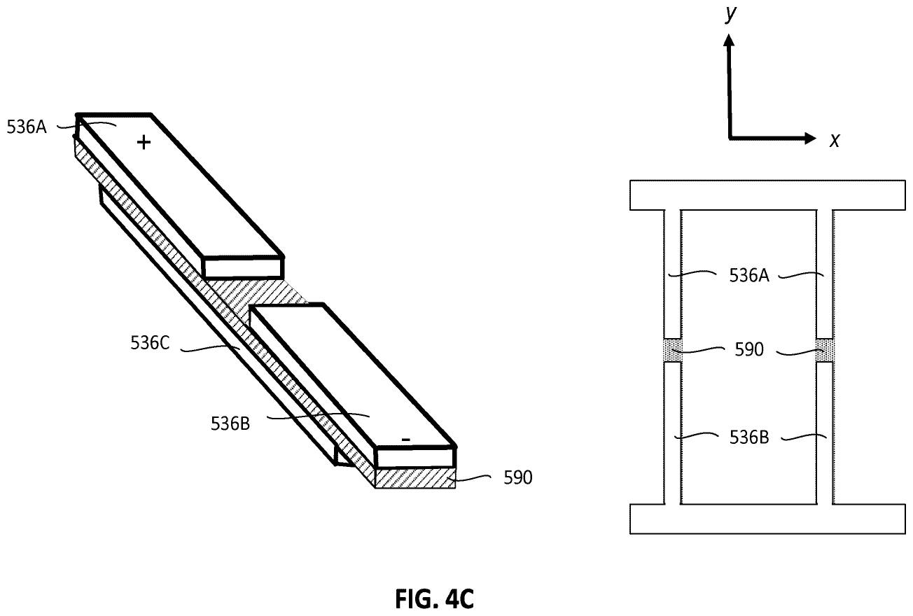

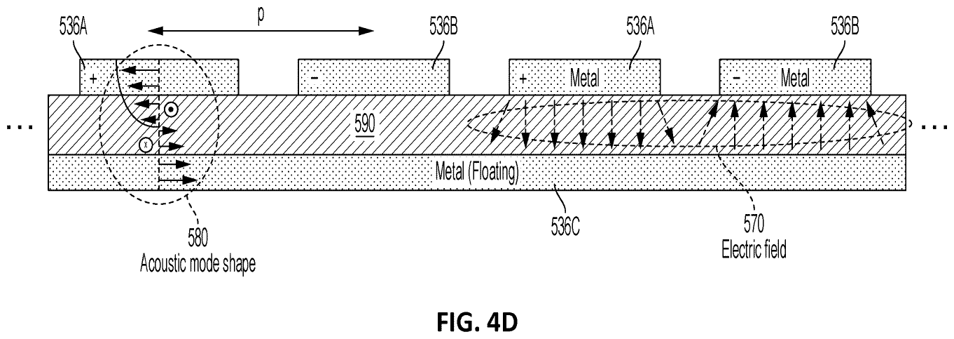

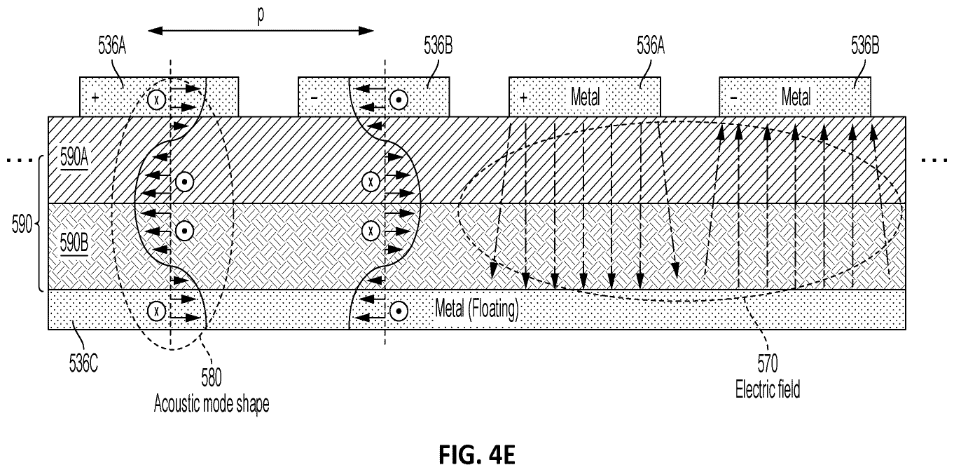

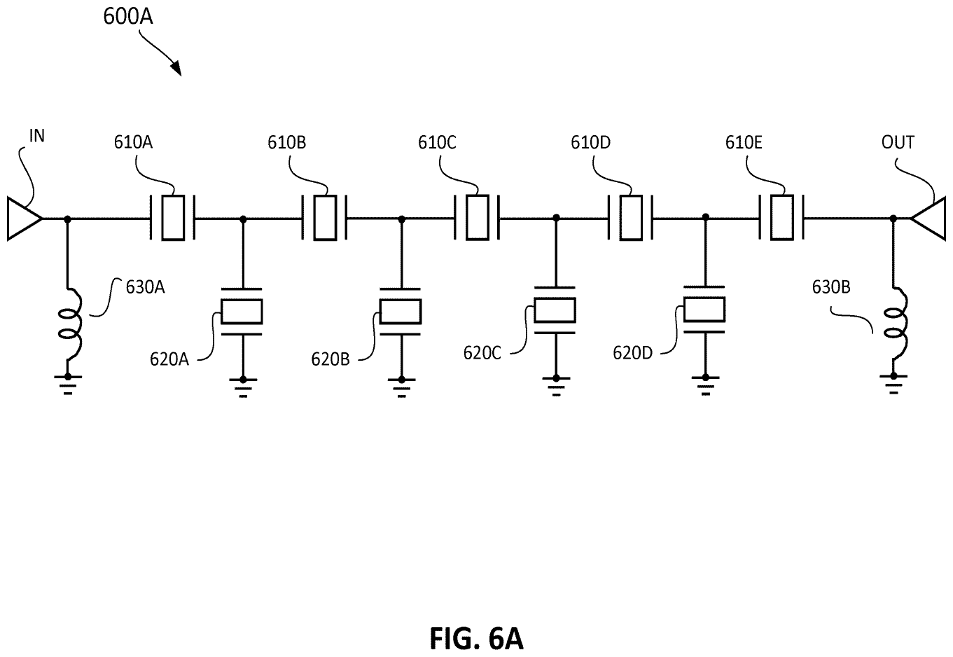

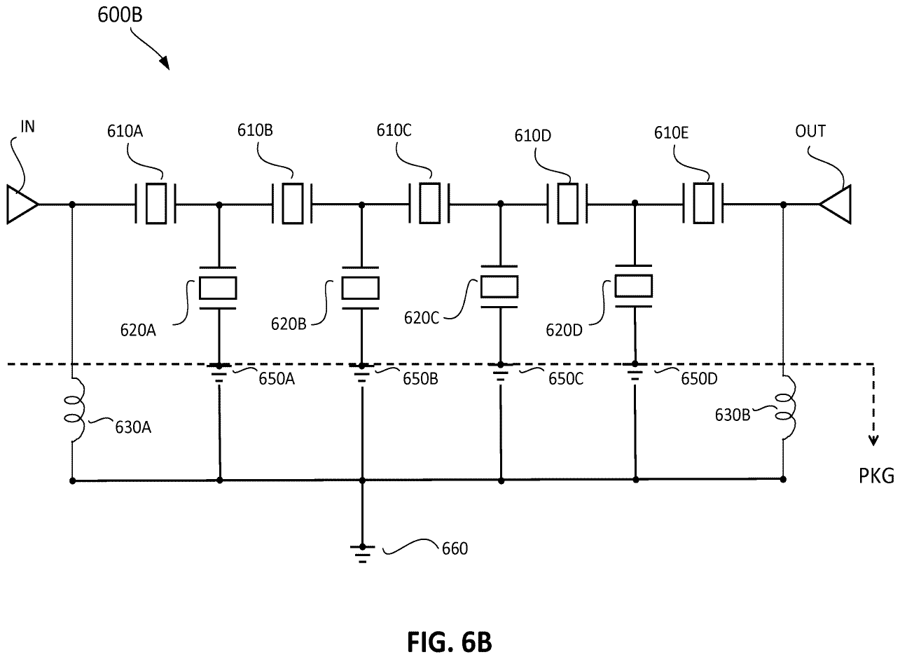

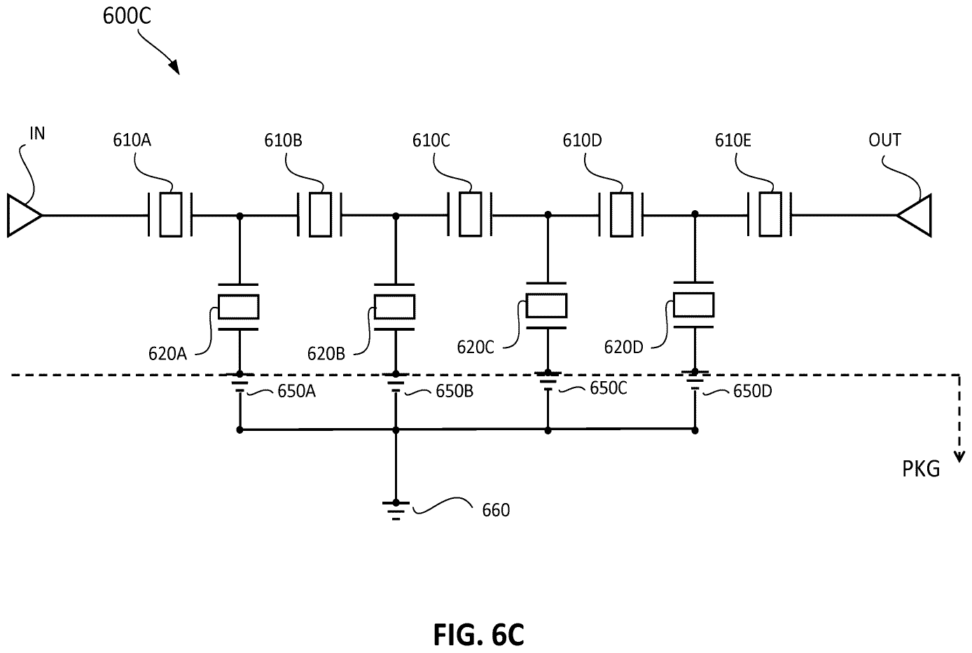

It is noted that while the exemplary aspects of the “inductor free” ladder filters as described below with respect to FIGS. 6A to 6C can be implemented with series and shunt resonators having vertically-excited structure as described in detail herein (in particular with regard to exemplary aspects shown in FIGS. 4A to 4E as follows), in an alternative aspect, such ladder filters can be implemented with one or more series or shunt resonators having an XBAR configuration as shown in FIG. 3C, for example. Moreover, in another exemplary aspect, some but not all of the shunt resonators and/or series resonators can have a combination of both vertically-excited structures and XBAR configurations as described herein.

FIG. 4A illustrates a schematic plan view and a perspective view of an acoustic resonator structure that is a refinement of the exemplary aspect of the film bulk acoustic resonator shown in FIGS. 2A-2C. FIG. 4B illustrates a cross-section view of the IDT configuration in FIG. 4A. As shown, the electrode fingers 436A (e.g., a pair) extend from a busbar 430 of a pair of busbars 430 and 432. An electrode 436A with a first potential extending from a first busbar 430 is on top (e.g., a first side) of the piezoelectric layer/material and an electrode (not shown) with a second potential (e.g., opposing potential) extending from a second busbar 432 is on the bottom (e.g., a second side) of the piezoelectric layer/material 410 such that the electrode on the top of the piezoelectric material at least partially overlaps the electrode on the bottom of the piezoelectric material. As should be readily appreciated, the top and bottom electrodes have an isolated piezoelectric between them, such that a cavity (e.g., an air gap or some sort of insulating material such as a dielectric) provides for increased isolation of each adjacent top and bottom electrode pair and an adjacent top and bottom electrode pair.

It is noted that while the piezoelectric layer 410 is shown to have a same width in the X-direction as the first and second electrodes (e.g., electrode fingers 436A), the piezoelectric layer 410 can have a larger width in the X direction in an alternative aspect, such that the electrodes have a smaller width than the piezoelectric layer (in the X-direction). The piezoelectric layer 410 can also have different cross-sectional shapes besides a rectangular shape, such as a hexagonal shape. Moreover, while the corners/edges of the piezoelectric layer and the electrics are shown to have a 90 degree or right angle, it should be appreciated that these corners or edges can be rounded or curved in practice, which may result from the deposition and/or etching processes as would be appreciated to one skilled in the art. Yet further, it should be appreciated that the electrodes could have a wider width (i.e., in the X-direction) than the piezoelectric layer and that the top and bottom electrodes can also have different widths from one another. It should be appreciated that these configurations can be applied to each of the embodiments shown in FIGS. 4A and 4B.

FIG. 4B illustrates how the electrode with the second potential extends into a cavity of the acoustic resonator, for example, cavity 125/225, as described above. As noted above, the cavity can be disposed directly in the substrate 420 as shown in FIG. 3A. Alternatively, the cavity can be disposed in an intermediate layer (e.g., a dielectric layer) between the substrate 420 and the IDT structure as shown in FIG. 3B.

Thus, according to the exemplary aspect shown in FIGS. 4A and 4B, an acoustic resonator is provided that includes a substrate 420; a piezoelectric layer 410 coupled to the substrate 420 either directly or via one or more intermediate layers; a first conductor pattern (e.g., electrode 436A) disposed on a first surface of the piezoelectric layer 410 (which has a first potential); and a second conductor pattern (e.g., electrode 436B) disposed on a second surface of the piezoelectric layer 410 opposite the first surface (which has a second and opposing potential). In this aspect, the first and second conductor patterns collectively form at least a pair of electrode fingers extending in a first direction with the piezoelectric layer disposed therebetween. As illustrated in FIG. 4A, piezoelectric may be removed in the x and y area between adjacent pairs of top and bottom electrodes such that each top and bottom electrode pair are substantially acoustically isolated from one another. The top and bottom electrodes having isolated piezoelectric between each top and bottom electrode can be isolated from an adjacent top and bottom electrodes having piezoelectric therebetween by a cavity (such as an air gap), some sort of insulating material such as a dielectric, or any other arrangement that allows for increased isolation of each adjacent top and bottom electrode pair and an adjacent top and bottom electrode pair. Acoustic resonator configurations can also have isolation between them as well. It is noted that the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

FIG. 4C illustrates a schematic plan view and a perspective view of an IDT configuration of another refinement of the exemplary aspect of the acoustic resonator shown in FIGS. 2A-2C. In this configuration, the two electrodes 436A and 436B with positive and negative potentials are both on a first side (e.g., top side or surface) of the piezoelectric layer 590 whereas a floating electrode 536C is on the opposing (e.g., second) side (e.g., bottom side or surface) of the piezoelectric layer. A similar configuration is described above with respect to FIGS. 1A-1C, except that this configuration includes a plurality (e.g., pair) of electrode fingers. The exemplary acoustic resonator structure shown in FIG. 4C is similar to that described above in FIGS. 4A and 4B, except that it provides for an acoustic resonator configuration in which a first busbar of the pair of busbars is coupled to the first conductor pattern, and a second busbar of the pair of busbars is coupled to the second conductor pattern. Moreover, the second conductor pattern is a floating electrode. It is noted that while the piezoelectric layer is shown to have a same width in the X-direction as the first and second electrodes, the piezoelectric layer can have a larger width in the X direction in an alternative aspect.

FIG. 4D is a graphical illustration of a primarily excited acoustic mode (also referred to as a primary acoustic mode) of interest in a resonator have a vertically-excited structure such as the film bulk acoustic resonator 200A shown in FIG. 2A. Referring to FIG. 4D, the film bulk acoustic resonator can include piezoelectric layer 590 and pairs of two electrodes (IDT fingers) 536A and 536B with positive and negative potentials, respectively. The two electrodes 536A and 536B can be both on the first side of the piezoelectric layer 590 and the floating electrode 536C is on the opposing side of the piezoelectric layer 590. The two electrodes 536A and 536B can correspond to conductor patterns 230 and 232, respectively, and the floating electrode 536C can correspond to back-side conductor pattern 234 according to an exemplary aspect.

In operation, an RF voltage is applied to the two electrodes 536A and 536B. This voltage creates a time-varying electric field between the fingers. The direction of the electric field is substantially vertical (i.e., vertically excited), or primarily perpendicular to the surface of the piezoelectric layer 590, as indicated by the arrows 570 labeled “Electric field.” Due to the high dielectric constant of the piezoelectric layer 590, the electric field can be highly concentrated in the piezoelectric layer relative to the air. The direction and magnitude of atomic motion in the film bulk acoustic resonator are represented by arrows 580. In the example shown in FIG. 4D, the atomic motion is in and out of the page. For example, the arrows pointing to the left represent the atomic motion that is out of the page (indicated by the dot) and the arrows pointing to the right represent the atomic motion that is into the page (indicated by the cross). According to an aspect of the disclosure, the electric field can be substantially vertical (i.e., orthogonal) to the direction of atomic motion. The degree of atomic motion, as well as the thickness of the piezoelectric layer 590, have been exaggerated for ease of visualization in FIG. 4D. While the atomic motions are predominantly lateral (i.e., horizontal as shown in FIG. 4D), the direction of acoustic energy flow of the primarily excited shear acoustic mode is substantially and/or primarily orthogonal to the surface of the piezoelectric layer.

FIG. 4E is a graphical illustration of a primarily excited acoustic mode (also referred to as a primary acoustic mode) of interest in a resonator have a vertically-excited structure such as the film bulk acoustic resonator 200A shown in FIG. 2A. Referring to FIG. 4E, the film bulk acoustic resonator can include the piezoelectric layer 590 and the two electrodes (IDT fingers) 536A and 536B with positive and negative potentials, respectively. The two electrodes 536A and 536B can be both on the first side of the piezoelectric layer 590 and the floating electrode 536C is on the opposing side of the piezoelectric layer 590. Again, the two electrodes 536A and 536B can correspond to conductor patterns 230 and 232, respectively, and the floating electrode 536C can correspond to back-side conductor pattern 234 according to an exemplary aspect.

In an example, the film bulk acoustic resonator shown in FIG. 4E is different from the film bulk acoustic resonator shown in FIG. 4D as follows. The piezoelectric layer 590 in FIG. 4E can include multiple piezoelectric layers such as piezoelectric layers 590A and 590B. For example, the piezoelectric layer 590 includes a COP structure where two layers 590A and 590B include piezoelectric material with opposite polarities or substantially opposite polarities in one or more axes. It is noted that the terms “opposite,” “opposing,” “opposed,” as used herein, may not necessarily mean exactly opposite, but instead could include the meaning of “substantially” opposite allowing for minor variations due to manufacturing tolerances.

In operation, an RF voltage is applied to the two electrodes 536A and 536B. This voltage creates a time-varying electric field between the fingers. The direction of the electric field is substantially vertical (i.e., vertically excited), or primarily perpendicular to the surface of the piezoelectric layer 590, as indicated by the arrows 570 labeled “Electric field.” Due to the high dielectric constant of the piezoelectric layer 590, the electric field can be highly concentrated in the piezoelectric layer relative to the air. The direction and magnitude of atomic motion in the film bulk acoustic resonator are represented by arrows 580. In the example shown in FIG. 4E, the atomic motion is in and out of the page. For example, the arrows pointing to the left represent the atomic motion that is out of the page (indicated by the dot) and the arrows pointing to the right represent the atomic motion that is into the page (indicated by the cross). According to an aspect of the disclosure, the electric field can be substantially vertical (i.e., orthogonal) to the direction of atomic motion. The degree of atomic motion, as well as the thickness of the piezoelectric layer 590, have been exaggerated for ease of visualization in FIG. 4E. While the atomic motions are predominantly lateral (i.e., horizontal as shown in FIG. 4E), the direction of acoustic energy flow of the primarily excited shear acoustic mode is substantially and/or primarily orthogonal to the surface of the piezoelectric layer.

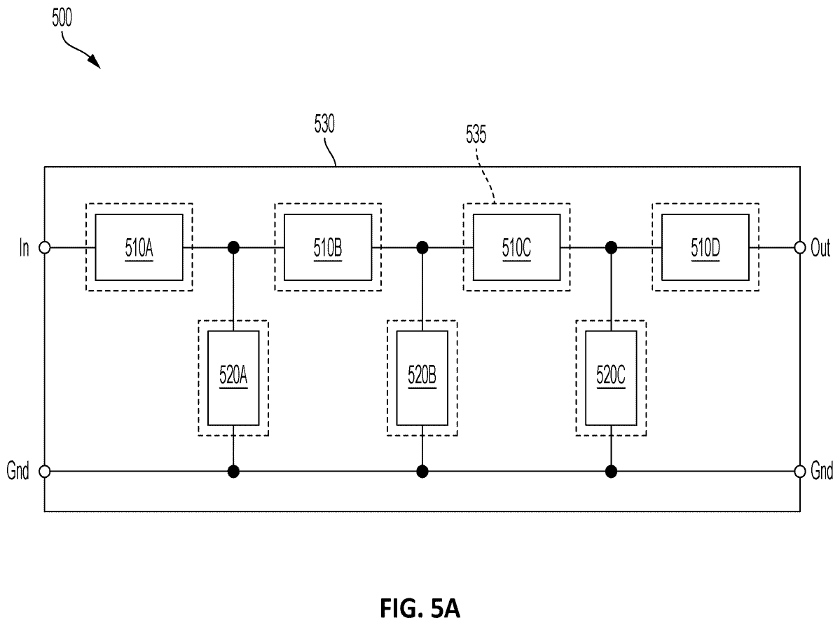

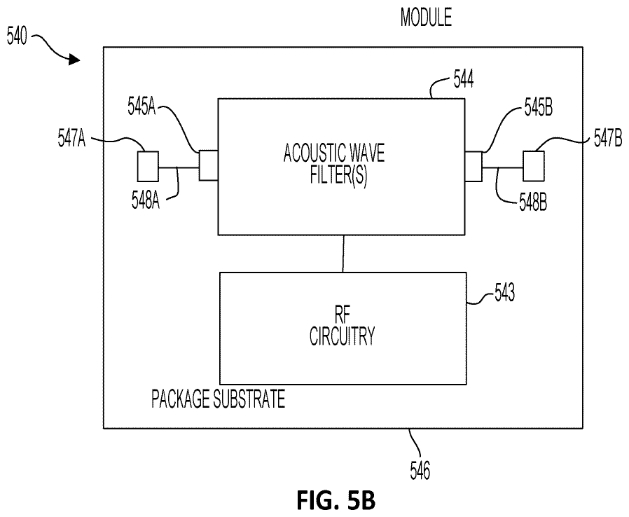

FIG. 5A is a schematic circuit diagram and layout for a high frequency bandpass filter 500 using acoustic resonators, such as the general film bulk acoustic resonator configurations 100 and/or 200A/200B described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, filter 500 is bidirectional and either port may serve as the input or output of the filter. At least three shunt resonators, such as the shunt resonators 520A, 520B and 520C, are connected from nodes between series resonators to a ground connection. A filter may contain additional reactive components, such as inductors, not shown in FIG. 5A. All the shunt resonators and series resonators are acoustic resonators (e.g., either of the film bulk acoustic resonator configurations 100 and/or 200A/200B as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however, different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an acoustic resonator configuration as described above with respect to FIGS. 1A-1C, 2A-2C and 4A-4C in which a diaphragm with IDT fingers spans over a cavity. Alternatively, each of the series resonators 510A, 510B, 510C, 510D and the shunt resonators 520A, 520B, and 520C can have an acoustic resonator configuration in which the series resonators 510A, 510B, 510C, 510D and/or the shunt resonators 520A, 520B, and 520C can be solidly mounted on or above a Bragg mirror, which in turn can be mounted on a substrate.

FIG. 5B is a schematic diagram of a radio frequency module that includes an acoustic wave filter device according to an exemplary aspect. In particular, FIG. 5B illustrates a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including film bulk acoustic resonators (e.g., the acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

FIG. 6A illustrates a filter structure implementing the acoustic resonator configurations according to an exemplary aspect. More specifically, in existing filter device designs that operate at high frequencies, inductors are required between the shunt resonators and the ground connection to compensate for lack of sufficient coupling in existing resonator designs. For example, an existing ladder filter design (e.g., as shown in FIG. 5A) using an existing acoustic resonator design will require inductors (not shown) between each of shunt resonators 520A, 520B and 520C and the ground “Gnd” connection of the chip. These inductors will enhance the electromechanical coupling of the filter to compensate for lack of coupling.

In contrast, according to an exemplary aspect, by implementing the acoustic resonator configurations described above with respect to FIGS. 4A to 4E, a filter device can be provided that is effectively “inductor free” (i.e., no inductors connected in the shunt paths to the ground connection).

FIG. 6A illustrates a circuit diagram of an “inductor free” ladder filter 600A (generally referred to as a “filter device”) according to an exemplary aspect. As shown, the filter device, i.e., ladder filter 600A, includes at least three series resonators, which in this case are five series resonators 610A to 610E, that are connected between a pair of ports, for example, input port “IN” and output port “OUT”. As further shown, at least two shunt resonators, which in this case are four shunt resonators 620A to 620D that are each connected between a ground connection and a node that is between a pair of the at least three series resonator or between the ground connection and a node between one port of the pair of ports and one series resonator of the at least three series resonators. As shown in the exemplary aspect, shunt resonator 620A is coupled between the ground connection and a node between series resonators 610A and 610B, shunt resonator 620B is coupled between the ground connection and a node between series resonators 610B and 610C, shunt resonator 620C is coupled between the ground connection and a node between series resonators 610C and 610D, and shunt resonator 620D is coupled between the ground connection and a node between series resonators 610D and 610E. It is also noted that while not shown, one or a plurality of capacitors can be connected in series with the series resonators 610A to 610E and/or in parallel with the shunt resonators 620A to 620D as would be appreciated to one skilled in the art.

According to the exemplary aspect, the filter device 600A is effectively “inductor free” in that the shunt resonators are each directly connected to the ground connection (e.g., by a wire line or conductive bump) without an inductor disposed therebetween. As described above, this configuration is enabled by the specific structural configuration of the vertically-excited acoustic resonators as described herein with respect to FIGS. 4A to 4E. More specifically, each of the series resonators 610A to 610E and each of the shunt resonators 620A to 620D is a vertically-excited acoustic resonator that each comprise a piezoelectric layer (e.g., piezoelectric layer 410 or 590) having a first surface and a second surface opposite the first surface, at least one first conductive layer (e.g., the electrode 436A or the electrode 536A) on the first surface of the piezoelectric layer 410/590, and a second conductive layer (e.g., the electrodes 536B or 536C) on the second surface of the piezoelectric layer 410/590. Moreover, the piezoelectric layer can be formed of lithium niobate, which provides for exception electromechanical coupling material.

According to this configuration, the vertically-excited acoustic resonators are structurally configured to provide an electromechanical coupling of at least 30% when a voltage is applied to the first conductive layer and the second conductive layer. In turn, the plurality of vertically-excited acoustic resonators are structurally configured to provide a fractional bandwidth of at least 25% relative to a bandwidth of the filter device, which enables the ladder filter 600A to provide a sufficient bandwidth at high frequencies without inductors being required between then shunt resonators and the ground connection (in comparison to existing filters), effectively reducing overall size and complexity of the filter device 600A. As used herein, the term “fractional bandwidth” is the filter passband width (Δf) divided by the center frequency (f_{c}), expressed as a percentage (e.g., ×100%). The passband width (Δf) is the difference between the upper and lower cutoff frequencies, and the center frequency (f_{c}) is the geometric mean of those cutoff frequencies. As such, the fractional bandwidth can equal (Δf/f_{c})×100% according to an exemplary aspect.

FIG. 6B illustrates a circuit diagram of a refinement of the “inductor free” ladder filter according to an exemplary aspect. As shown, the filter device 600B includes a similar ladder configuration as described above with respect to FIG. 6A that includes five series resonators 610A to 610E connected between a pair of ports (e.g., input port “IN” and output port “OUT”). Moreover, four shunt resonators 620A to 620D are configured in the ladder filter in a similar aspect as also described above. In this exemplary aspect, each of the series resonators 610A to 610E and the shunt resonators 620A to 620D can be mounted to a single chip that comprises the pair of ports.

In turn, the chip can be mounted on a separate or additional chip, which is identified as a package “PKG” and can be a printed circuit board (“PCB”) in an exemplary aspect. As shown, the single chip can have a plurality of conductive contacts (e.g., ground contacts 650A, 650B, 650C, and 650D) that are each electrically coupled (e.g., via a conductive trace) to the shunt resonators 620A to 620D, respectively. The ground contacts 650A to 650D (e.g., conductive bumps) can be coupled to an external ground contact 660 of the printed circuit board that comprises the ground connection. In addition, the additional chip (e.g., printed circuit board “PCK”) can include a pair of matching inductors 630A and 630B that are respectively coupled to the pair of ports of the single chip and the ground connection 660.

It is reiterated that the filter device 600B may include a residual inductance between each of the shunt resonators 620A to 620D and the ground connection (e.g., ground contacts 650A to 650D) due to the conductive traces or wiring. This residual inductance will be equal to or less than 0.1 nanohenries (nH) in an exemplary aspect. This level of inductance is comparatively low when considering that the filter device 600B has no on-chip inductors, but is enabled by way of the large coupling of the filter device 600B. The filter device 600B may have no on-chip inductors when the shunt resonators 620A to 620D are connected to ground with an inductor therebetween. The term “residual inductance,” as used herein, is an inductance that can be measured across the filter (e.g., due to the conductive traces or wiring) despite having no inductors connected to ground and to the shunt resonators 620A to 620D.

It is also reiterated that while five series resonators 610A to 610E and four shunt resonators 620A to 620D are shown, the ladder filters 600A and/or 600B can comprise at least three series resonators and at least two shunt resonators in an exemplary aspect. Moreover, each of the plurality of resonators can be vertically excited acoustic resonators as described above with respect to FIGS. 4A to 4E, for example. That is, each of the series resonators and the shunt resonators can comprise a pair of busbars that includes the first busbar that is coupled to the at least one first conductive layer and a second busbar that is coupled to the second conductive layer in an exemplary aspect. Alternatively, in another exemplary aspect, each of the series resonators and the shunt resonators can comprise a pair of busbars that includes the first busbar that is coupled to the at least one first conductive layer, and where the second conductive layer of each resonator is a floating electrode. Moreover, in the exemplary aspect, the piezoelectric layer of each of the resonators preferably comprises lithium niobate due to its high electromechanical coupling characteristics.

As a result of this configuration of the exemplary ladder filter circuit 600B, the at least three series resonators (e.g., three or more of resonators 610A to 610E) and the at least two shunt resonators (e.g., two or more of resonators 620A to 620D) are structurally configured to provide an electromechanical coupling of at least 30% when a voltage is applied to the respective conductive layers of the resonators. In turn, this configuration provides a fractional bandwidth of at least 25% relative to a bandwidth of the filter device 600B, without requiring inductors between each of the shunt resonators (e.g., resonators 620A to 620D) and ground connection 660 (and ground contacts 650A to 650D, which can be intermediate conductive bumps).

FIG. 6C illustrates a circuit diagram of a refinement of the “inductor free” ladder filter according to an exemplary aspect. In particular, the filter device 600C is a ladder filter with a similar configuration as described above with respect to FIG. 6B. The components, including the plurality of resonators have the same configuration and the description of such components will not be repeated herein. However, in the exemplary aspect, matching inductors 630A and 630B as shown in FIG. 6B are omitted in an alternative aspect when the vertically excited acoustic resonators have an even higher coupling, such as the COP structure described above and shown in FIG. 4E.

It is also noted that the filter devices 600A, 600B and 600C illustrated in FIGS. 6A to 6C can be provided with the following parameters: gamma is 1.44 (41%), 1.6 (k²=38.5), 1.8 (k²=35.7), 2.1 (k²=32.3). It is note that gamma is a parameter that characterizes the piezoelectric coupling of the resonator. That is gamma=fr²/(fa²−fr²), where fr is the resonance frequency and fa is the antiresonance frequency. In this aspect, a small gamma value indicates a large electromechanical coupling k². Moreover, the formula k²=1/(1+gamma) can be provided to characterize the coupling. Of course, a large value k² indicates a large electromechanical coupling.

In an exemplary aspect, the ladder filters can be configured to have a symmetric configuration. That is, series resonators 610A and 610E can be substantially identical (e.g., in terms of stack thickness, metallization ratios, layer thickness, etc.), series resonators 610B and 610D can be substantially identical, shunt resonators 620A and 620D can be substantially identical, and shunt resonators 620B and 620C can be substantially identical. Effectively, the filter devices can be optimized without input shunt matching inductors as described above. As also noted above, these configurations allow for some matching inductors (i.e., coupled to the input and output ports as shown in FIG. 6B), which are usually on a separate chip.

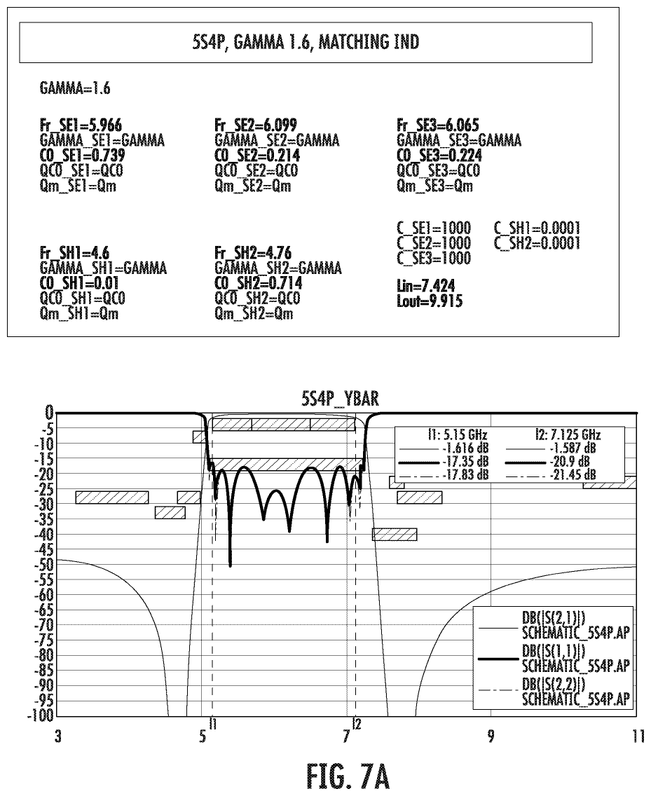

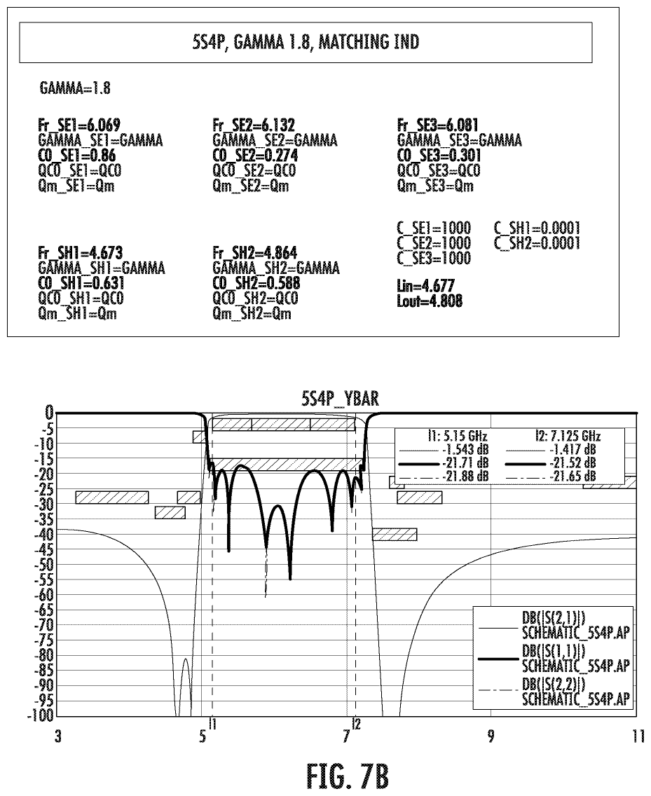

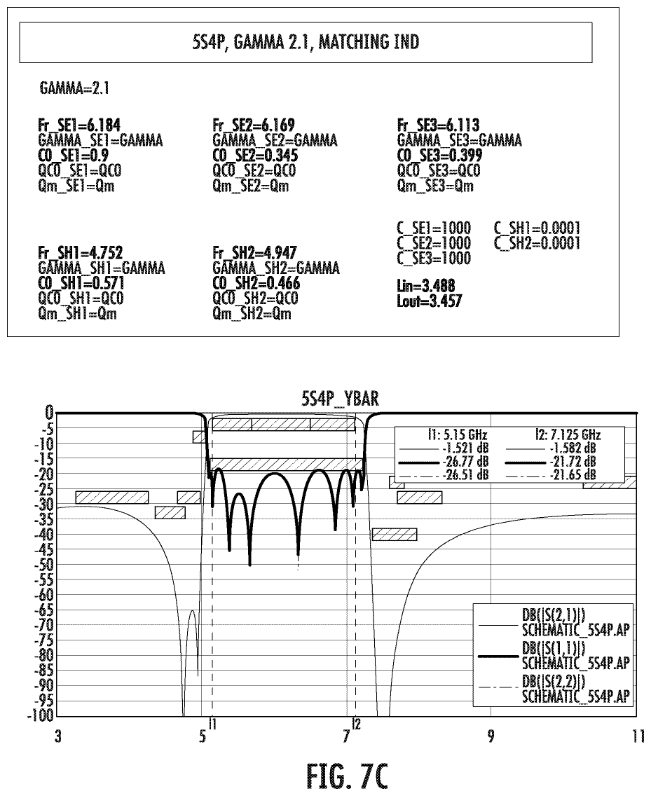

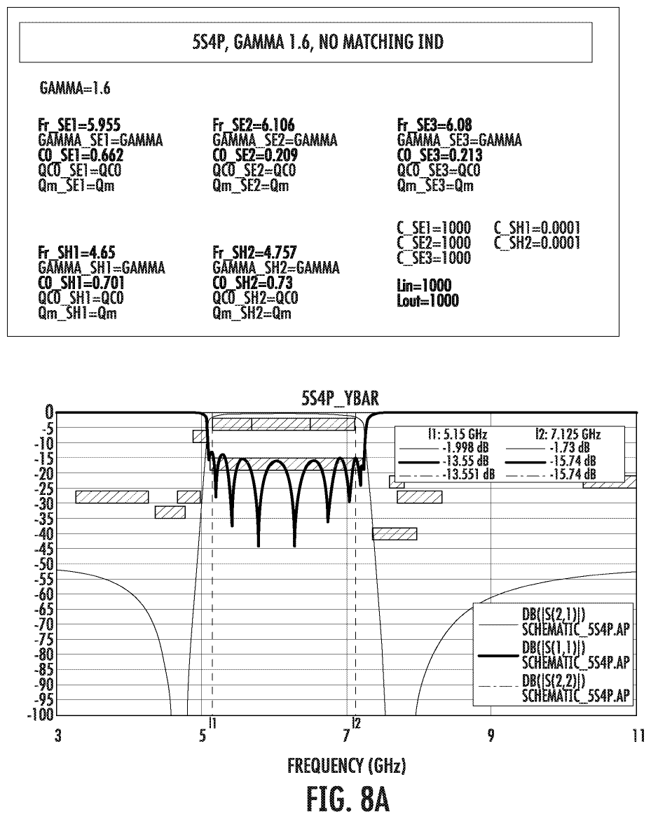

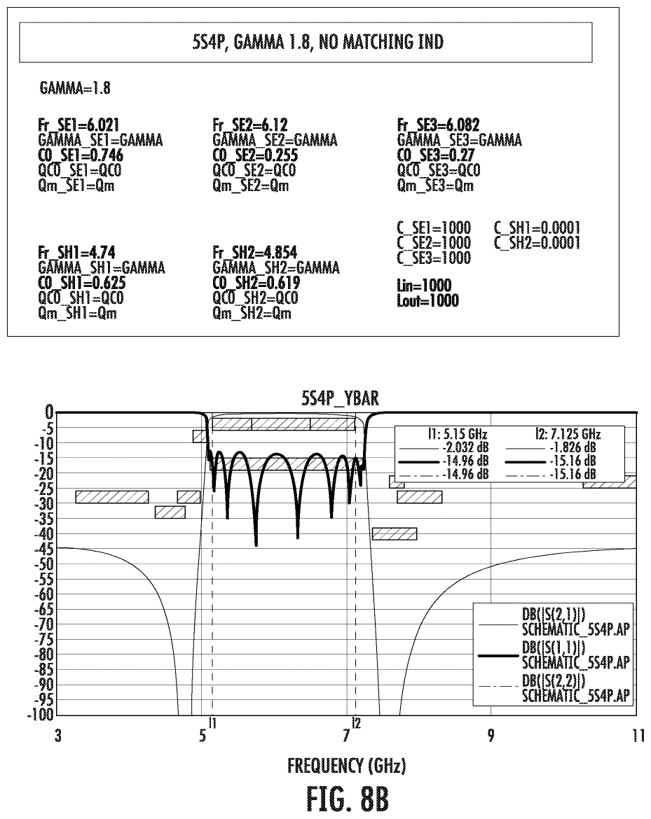

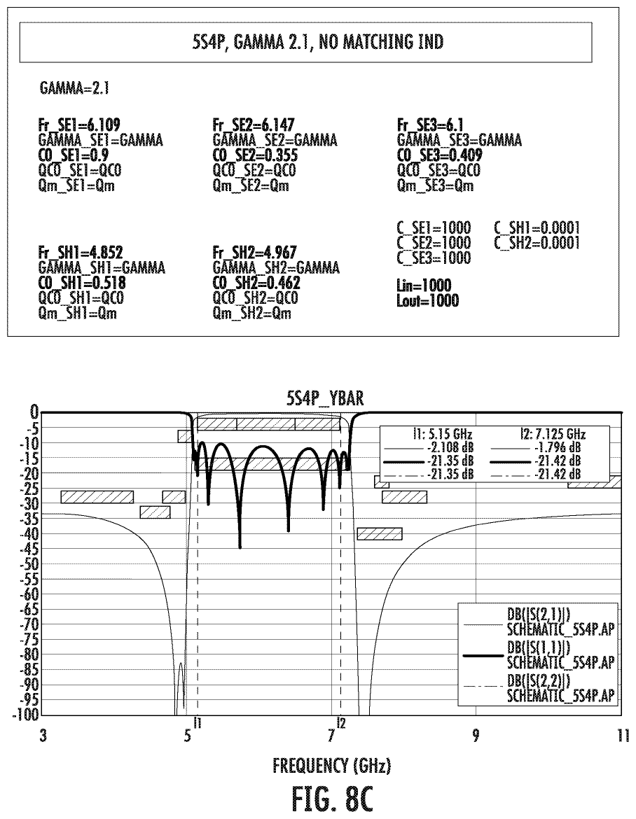

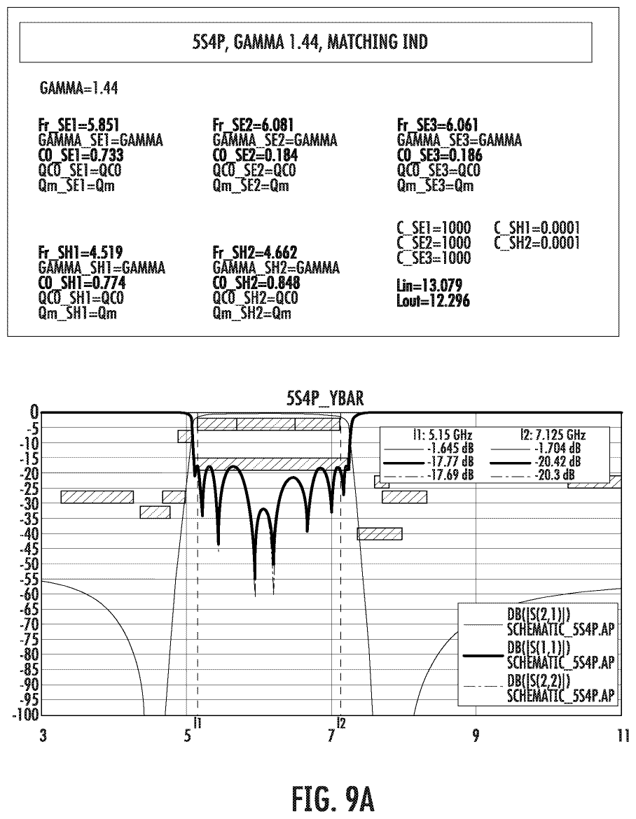

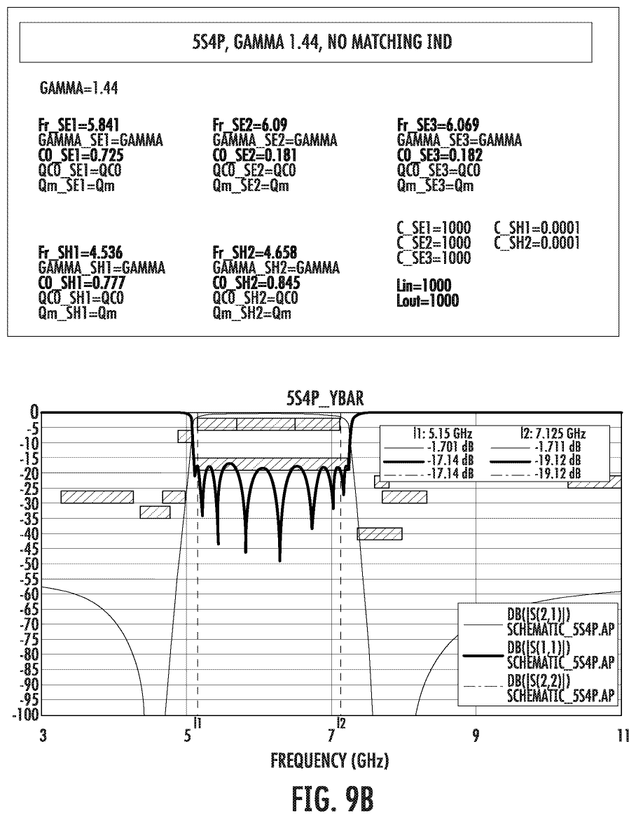

FIGS. 7A-7C illustrate simulation showing admittance for a filter device with matching inductors according to a conventional ladder filter design as described above, except that the simulations all use resonators with different couplings, i.e., gamma=1.6, 1.8, and 2.1, respectively. On the other hand, FIGS. 8A-8C illustrate simulation showing admittance for a filter device with inductors according to an exemplary aspect. FIGS. 9A and 9B compare the same general ladder configuration (e.g., five series resonators and 4 shunt resonators) with a gamma value of 1.44 and with and without matching inductors as described herein. According to the exemplary aspects, each of the plots shown in FIGS. 7A-7C, 8A-8C and 9A-9B can be simulated using finite element method (FEM) simulation techniques and shown admittance (in the Y axis) as a function of frequency GHZ. (in the X axis).

According to exemplary aspects, the simulations shown in FIGS. 7A-C demonstrate how the choice of resonator coupling (e.g., the gamma value) affects the filter performance when allowing matching inductors. The smallest gamma design as shown in FIG. 7A illustrates the best rejection and overall performance.

The simulations in FIGS. 8A-C demonstrate how the filter performance suffers when no matching inductors are allowed. In particular, the in-band RL of each filter gets worse, though the lowest gamma version shown in FIG. 8A is manageable, for example. Moreover, it is noted that the largest electromechanical coupling k² achieved from the acoustic resonators described herein has a gamma value of approximately 1.44. FIGS. 9A and 9B demonstrate the expected performance using resonators with this coupling. It should also be appreciated that the performance is still very good even without inductors as shown in FIG. 9B.

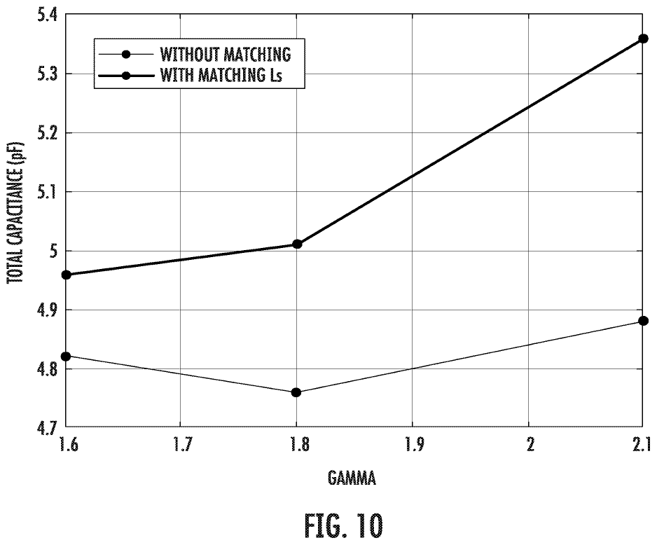

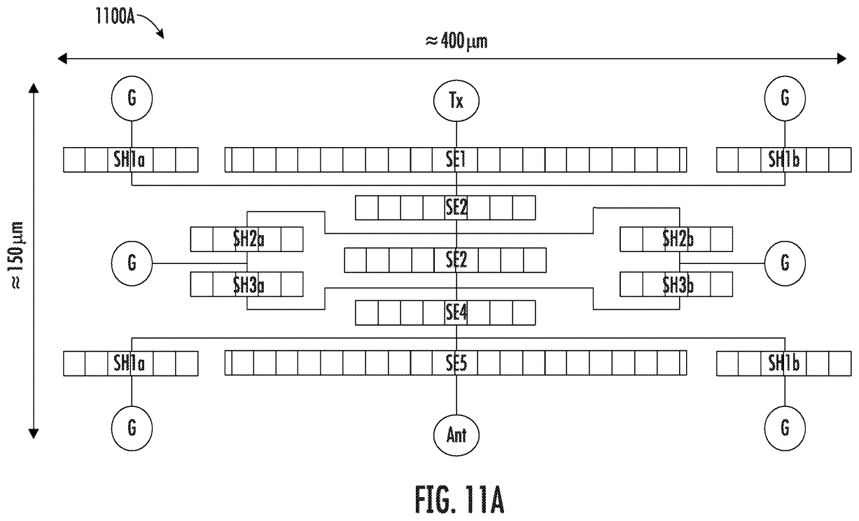

FIG. 10 illustrates a simulation showing capacity and density according to an exemplary aspect. More particularly, the plot shows total capacitance (in pF) for each of the six filters where the total capacitance is a proxy for total resonator area. In this aspect, a layout is created for γ=2.1 with matching L filter, which is the largest filter. The approximate capacitance density for conventional vertically excited acoustic resonators at Wi-Fi full band frequency is 4.32 pF/m². Assuming that each of the acoustic resonators has an aperture of 10 μm for purposes of the simulation, the lengths of each are: Series: (208, 80, 92, 80, 208)×μm, and shunts: (132, 108, 108, 132)×μm. As shown, the total capacitance substantially increases for the filter devices with matching inductors as gamma increases. In contrast, the total capacitance remains substantially content (with a slight dip) the filter devices without matching inductors as gamma increases.

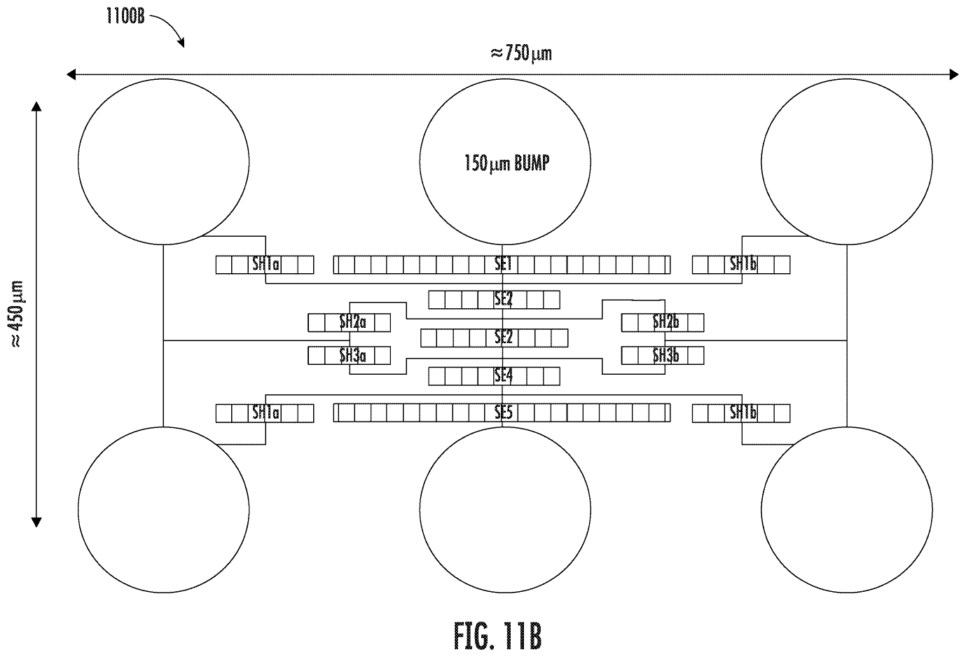

FIGS. 11A and 11B illustrates exemplary layouts of the filter structure according to an exemplary aspect. In particular, FIG. 11A illustrates a filter layout 1100A without contact bumps and FIG. 11B illustrates a filter layout 1100B with contact bumps. It should be appreciated that resonators SE1-SE5 correspond to resonators 610A to 610E. Similarly, sub-resonators SH1a and SH1b correspond to sub-resonators of shunt resonators 620A, sub-resonators SH2a and SH2b correspond to sub-resonators of shunt resonator 620B, sub-resonators SH3a and SH3b correspond to sub-resonators of shunt resonator 620C, and sub-resonators SH4a and SH4b correspond to sub-resonators of shunt resonators 620D. As shown in FIG. 11A, “G” corresponds to the ground connections, which are shown as conductive bumps in FIG. 11B. The contacts “Tx” and “Ant” correspond to the input port IN and the output port OUT with the five series resonators therebetween as would be appreciated to one skilled in the art.

According to the exemplary aspects of the filter device described herein, a plurality of vertically-excited acoustic resonators are included in the filter and are structurally configured to provide a fractional bandwidth of at least 25% relative to a bandwidth of the filter device, which enables the ladder filter 600A to provide a sufficient bandwidth at high frequencies without inductors between then shunt resonators and the ground connection. Effectively, this filter configuration reduces the overall size and complexity of the filter device 600A. Moreover, shunt inductors used in conventional ladder filters can cause a flyback, which is a degradation of the filter in higher ranges. Such inductors also have a low-quality factor that leads to filter loss in that impedance can change significantly over low to high frequency, which means that the rejection suffers. The exemplary configurations eliminate the need to include shunt inductors and thus can also reduce or eliminate a flyback effect and minimize filter loss.

Throughout this description, the embodiments and examples shown should be considered as exemplary, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A filter device comprising:
at least three series resonators connected between a pair of ports; and
at least two shunt resonators that are each connected between a ground connection and a node between a pair of the at least three series resonators or between the ground connection and a node between one port of the pair of ports and one series resonator of the at least three series resonators,
wherein each of the at least three series resonators and the at least two shunt resonators comprise:
a piezoelectric layer having a first surface and a second surface opposite the first surface,
at least one first conductive layer on the first surface of the piezoelectric layer, and
a second conductive layer on the second surface of the piezoelectric layer;
wherein the at least two shunt resonators are each connected to the ground connection without an inductor disposed therebetween.

2. The filter device according to claim 1, further comprising a residual inductance between each of the at least two shunt resonators and the ground connection that is equal to or less than 0.1 nanohenries (nH).

3. The filter device according to claim 1, wherein the at least three series resonators and the at least two shunt resonators are structurally configured to provide a fractional bandwidth of at least 25% relative to a bandwidth of the filter device.

4. The filter device according to claim 3, wherein the at least three series resonators and the at least two shunt resonators are each vertically excited acoustic resonators that are structurally configured to provide an electromechanical coupling of at least 30% when a voltage is applied to the at least one first conductive layer and the second conductive layer.

5. The filter device according to claim 1, wherein each of the at least three series resonators and the at least two shunt resonators are mounted to a single chip that comprises the pair of ports and a plurality of conductive contacts that are coupled to an external ground contact comprising the ground connection.

6. The filter device according to claim 5, further comprising an additional chip that includes a pair of matching inductors that are respectively coupled to the pair of ports of the single chip and the ground connection.

7. The filter device according to claim 1, wherein each of the at least three series resonators and the at least two shunt resonators further comprises a pair of busbars that includes a first busbar that is coupled to the at least one first conductive layer and a second busbar that is coupled to the second conductive layer.

8. The filter device according to claim 1, wherein each of the at least three series resonators and the at least two shunt resonators further comprises a pair of busbars that includes a first busbar that is coupled to the at least one first conductive layer, and the second conductive layer of each of the at least three series resonators and the at least two shunt resonators is a floating electrode.

9. The filter device according to claim 1, wherein the piezoelectric layer of each of the at least three series resonators and the at least two shunt resonators comprise lithium niobate.

10. A filter device comprising:
at least three series resonators connected between a pair of ports; and
at least two shunt resonators that are each connected between a ground connection and a node between a pair of the at least three series resonators or between the ground connection and a node between one port of the pair of ports and one of the at least three series resonators,
wherein the at least two shunt resonators are each connected to the ground connection without an inductor disposed therebetween, and
wherein the at least three series resonators and the at least two shunt resonators are structurally configured to provide a fractional bandwidth of at least 25% relative to a bandwidth of the filter device.

11. The filter device according to claim 10, wherein each of the at least three series resonators and the at least two shunt resonators are vertically excited acoustic resonators that each comprise:
a piezoelectric layer having a first surface and a second surface opposite the first surface,
at least one first conductive layer on the first surface of the piezoelectric layer, and
a second conductive layer on the second surface of the piezoelectric layer.

12. The filter device according to claim 10, further comprising a residual inductance between each of the at least two shunt resonators and the ground connection that is equal to or less than 0.1 nanohenries (nH).

13. The filter device according to claim 11, wherein the at least three series resonators and the at least two shunt resonators are structurally configured to provide an electromechanical coupling of at least 30% when a voltage is applied to the at least one first conductive layer and the second conductive layer.

14. The filter device according to claim 10, wherein each of the at least three series resonators and the at least two shunt resonators are mounted to a single chip that comprises the pair of ports and a plurality of conductive contacts that are coupled to an external ground contact comprising the ground connection.

15. The filter device according to claim 14, further comprising an additional chip that includes a pair of matching inductors that are respectively coupled to the pair of ports of the single chip and the ground connection.

16. The filter device according to claim 11, wherein each of the at least three series resonators and the at least two shunt resonators further comprises a pair of busbars that includes a first busbar that is coupled to the at least one first conductive layer and a second busbar that is coupled to the second conductive layer.

17. The filter device according to claim 11, wherein each of the at least three series resonators and the at least two shunt resonators further comprises a pair of busbars that includes a first busbar that is coupled to the at least one first conductive layer, and the second conductive layer of each of the at least three series resonators and the at least two shunt resonators is a floating electrode.

18. The filter device according to claim 11, wherein the piezoelectric layer of each of the at least three series resonators and the at least two shunt resonators comprise lithium niobate.

19. A radio frequency module comprising:
a filter device including:
at least three series resonators connected between a pair of ports; and
at least two shunt resonators that are each connected between a ground connection and a node between a pair of the at least three series resonators or between the ground connection and a node between one port of the pair of ports and one of the at least three series resonators,
wherein the at least two shunt resonators are each connected to the ground connection without an inductor disposed therebetween, and
wherein the at least three series resonators and the at least two shunt resonators are structurally configured to provide a fractional bandwidth of at least 25% relative to a bandwidth of the filter device.

20. The radio frequency module according to claim 19,
wherein each of the at least three series resonators and the at least two shunt resonators are vertically excited acoustic resonators that each comprise:
a piezoelectric layer having a first surface and a second surface opposite the first surface,
at least one first conductive layer on the first surface of the piezoelectric layer, and
a second conductive layer on the second surface of the piezoelectric layer, and
wherein the at least three series resonators and the at least two shunt resonators are structurally configured to provide an electromechanical coupling of at least 30% when a voltage is applied to the at least one first conductive layer and the second conductive layer.
